(19) United States
(12) Patent Application Publication
(10) Pub. No.: US 2025/0211138 A1
(43) Pub. Date: Jun. 26, 2025

(54) Linear Motion Platform Utilizing an Externally Threaded Piezoelectric Actuator and Operating Method

(71) Applicant: NANJING UNIVERSITY OF AERONAUTICS AND ASTRONAUTICS, Nanjing (CN)

(72) Inventors: Liang WANG, Nanjing (CN); Botao JIA, Nanjing (CN); Shuang Li, Nanjing (CN); Ruijun WANG, Nanjing (CN)

(73) Assignee: NANJING UNIVERSITY OF AERONAUTICS AND ASTRONAUTICS, Nanjing (CN)

(21) Appl. No.: 18/981,571

(22) Filed: Dec. 15, 2024

(30) Foreign Application Priority Data
Dec. 26, 2023 (CN) 202311805053.6

(51) Int. Cl. H02N 2/04; H02N 2/06; H10N 30/853; H10N 30/88

(52) U.S. Cl. CPC H02N 2/043; H02N 2/065; H10N 30/853; H10N 30/88

(57) ABSTRACT

Disclosed are a linear motion platform driven by an external thread piezoelectric actuator and a method thereof. The linear motion platform comprises an actuator, a first fixed support, a second fixed support, a rolling bearing, a connecting plate, an objective table, and M guide assemblies. The actuator comprises a metal matrix, a driving nut, a first piezoelectric assembly, a second piezoelectric, a front beam, a rear beam, and first and second fixed bolts. The platform can drive the objective table to perform a linear motion directly through the actuator, is simple and compact in structure, high in precision, capable of being self-locked in case of power failure and good in universality, and has relatively high application values in the field of precision transmission.

### CROSS-REFERENCE TO RELATED APPLICATION

The present takes priority from a Chinese Patent Application No. 2023118050536, filed on Dec. 26, 2023, the entire contents of the application is incorporated herein by reference in its entirety.

### TECHNICAL FIELD

The disclosure relates to the technical field of piezoelectric driving, and particularly to a linear motion platform driven by an external thread piezoelectric actuator and a method thereof.

### BACKGROUND

The development of conventional electric precision assembly manufacturing industry is one of important factors that affect economic growth and technological progress of a country. With rapid development of modern scientific and technological level, an increasing number of technical indexes are improved continuously. In the fields of precision optical instruments, precision medical equipment, aerospace, smart robots and the like, a conventional electromagnetic motor has been gradually unable to meet the growing technical requirements, for example, requirements on microminiaturization, high integration, high reliability, and multifunctionality. Besides, due to the limitation of the principle and structural form of the electromagnetic motor, the newly proposed requirements on motors such as being short, small, light, thin, and electromagnetic interference-free and having rapid dynamic response cannot be met. On this basis, countries all over the world start to explore micro motors that meet the above requirements. A piezoelectrically driven motor is one of comparative mature technologies in micro motors.

A piezoelectric actuator forces an elastomer to generate vibration based on the fundamental principle of an inverse piezoelectric effect of a smart material and then converts vibration through friction between a stator and a rotor into a macroscopic motion. Thanks to the unique working principle of the piezoelectric actuator, the piezoelectric actuator has the advantages of simple and compact structure, high respond speed, high positioning precision and no electromagnetic interference and the like. At present, a linear piezoelectric actuator has been successfully applied to the fields of a precision linear motion platform, an automatic focusing device of a camera, a medical microinjector and the like. Applying the piezoelectric actuator to the precision linear motion platform to realize precision positioning is one of the research hotspots nowadays.

### SUMMARY OF THE INVENTION

To overcome deficiencies in the background art, the application provides a linear motion platform driven by an external thread piezoelectric actuator and a method thereof.

The disclosure adopts the following technical solutions to solve the above technical problems:
First, the application provides a linear motion platform driven by an external thread piezoelectric actuator, including an actuator, a first fixed support, a second fixed support, a rolling bearing, a connecting plate, an objective table, and M guide assemblies, where M is a natural number greater than or equal to 1;
the actuator includes a metal matrix, a driving nut, a first piezoelectric assembly, a second piezoelectric, a front beam, a rear beam, and first and second fixed bolts;
the metal matrix is cylindrical, with an external thread being arranged in the middle of an outer wall thereof, so that the outer wall includes a first connecting part, a threaded part, and a second connecting part connected in sequence, and the first connecting part and the second connecting part are symmetrical about the threaded part; a first blind threaded hole and a second blind threaded hole matching with the first fixed bolt and the second fixed bolt are formed in both ends of the metal matrix, respectively;
the driving nut sleeves the metal matrix and is in threaded connection to the metal matrix;
the first piezoelectric assembly and the second piezoelectric assembly are the same in unit structure and each include M piezoelectric units laminated in sequence, where M is a natural number greater than or equal to 1;
the piezoelectric unit includes first to fourth dual-partition piezoelectric ceramic plates laminated in sequence, and an electrode plate is arranged between every two adjacent piezoelectric ceramic plates; the piezoelectric ceramic plates laminated can form a “sandwiched configuration” in the actuator and are fixed to the actuator through bolts to improve the spatial utilization ratio of the actuator, and moreover, it is convenient to applying an excitation voltage to the piezoelectric ceramic plates through the electrode plates.
the first to fourth dual-partition piezoelectric ceramic plates are the same in structure, all being in a shape of a circular ring, outer diameters thereof are the same as an outer diameter of a cross section of the first connecting part, and the two partitions both are polarized in a thickness direction and directions of polarization are opposite;
polarization boundaries of the first and second dual-partition piezoelectric ceramic plates are coplanar and the directions of polarization on the same side are opposite, polarization boundaries of the third and fourth dual-partition piezoelectric ceramic plates are coplanar and the directions of polarization on the same side are opposite, and the polarization boundaries of the second and third dual-partition piezoelectric ceramic plates are perpendicular to each other;
the front beam and the rear beam are the same in structure, both being cylinders with a same cross section as that of the first connecting part, and are each provided with a through hole along an axis;
the first fixed bolt passes through the front beam and the first piezoelectric assembly in sequence and is then in threaded connection to the first blind threaded hole to clamp the first piezoelectric assembly between the front beam and the metal matrix; the second fixed bolt passes through the rear beam and the second piezoelectric assembly in sequence and is then in threaded connection to the second blind threaded hole to clamp the second piezoelectric assembly between the rear beam and the metal matrix; and the first piezoelectric assembly and the second piezoelectric assembly are symmetrical;
the ends of the front beam and the rear beam away from the metal matrix are fixedly connected to the outside through the first fixed support and the second fixed support, respectively;
the guide assembly includes a linear bearing and a guide bar, wherein the linear bearing sleeves outside the guide bar, matches with the guide bar, and is slidable freely relative to the guide bar;
the connecting plate is provided with a first mounting hole for mounting the rolling bearing 7 and M second mounting holes in one-to-one correspondence to the guide assemblies;
an outer ring of the rolling bearing is fixedly connected to the connecting plate at the first mounting hole thereof, and an inner ring is coaxially fixedly connected to the driving nut;
the linear bearings of the M guide assemblies are fixed in the second mounting holes corresponding thereto one by one, both ends of the guide bars of the M guide assemblies are fixedly connected to the first fixed support and the second fixed support, respectively, and the guide bars of the M guide assemblies both are parallel to the metal matrix. The parallelly arranged guide bars can guarantee that the objective table equipped with the linear bearing moves axially to guide the objective table, so that the linearity of the objective table is improved.

The connecting plate is fixedly connected to the objective table.

In an embodiment of the application, the driving nut is in interference fit with the inner ring of the rolling bearing, and a snap ring is arranged between the driving nut and the inner ring of the rolling bearing. The snap ring can limit the rolling bearing axially, so that the assembly error is reduced.

In an embodiment of the application, the rolling bearing is a ceramic bearing.

In an embodiment of the application, the first connecting part and the second connecting part each are circumferentially and uniformly provided with a plurality of milling planes to facilitate assembly.

Second, the application further discloses a working method of the linear motion platform driven by an external thread piezoelectric actuator, including the following steps:
if it is needed to drive the objective table to move forward:
grounding the metal matrix, applying a first signal to the first and second piezoelectric ceramic plates of each piezoelectric unit in the first and second piezoelectric assemblies, and applying a second signal to the third and fourth piezoelectric ceramic plates of each piezoelectric unit in the first and second piezoelectric assemblies, where the first and second signals are sinusoidal voltage signals with a phase difference of π/2, so that particles on the thread of the metal matrix vibrate at a high frequency and with a small amplitude to enable the driving nut to rotate through a rubbing action; the connecting plate driven by the driving unit moves forward to drive the objective table to move forward; and
if it is needed to drive the objective table to move reversely, just adjusting the phase difference between the first and second signals as −π/2.

Compared with the prior art, the application has the following beneficial effects:

1. According to the motion platform provided in the embodiments of the application, structural characteristics of a lead screw nut are fully used, and the metal matrix is taken as a shock excitation part, which is convenient in clamping, so that the piezoelectrically driven precision linear platform is simple and compact in structure, and the metal matrix matches with fine pitch thread of the driving nut to guarantee that the platform can achieve high-precision transmission and realize precise positioning. Due to the uniqueness of the piezoelectric driving principle, the motion platform has the advantages of high response speed, self-locking in case of power failure, strong anti-electromagnetic interference ability and the like.

2. According to the motion platform provided in the embodiments of the application, by means of the structure of the lead screw nut, a length of the threaded section of the metal matrix can be designed according to an actual demand to meet the requirements on a moving distance of the precision linear platform in different occasions, so that the disclosure is of good universality.

### BRIEF DESCRIPTION OF FIGURES

FIG. 1 is a schematic structural diagram of a linear motion platform in an embodiment;

FIG. 2 is a schematic diagram of polarization partitioning of piezoelectric ceramic plates in a first piezoelectric assembly of the linear motion platform in an embodiment;

FIG. 3 is a schematic diagram of applying a voltage in the linear motion platform in an embodiment;

FIG. 4 is a schematic simulation diagram of the linear motion platform in an embodiment during work.

FIG. 5 is a schematic enlarged view of the partial structure at position A in FIG. 1;

FIG. 6 is a schematic three-dimensional view of the structure in FIG. 2; and

FIG. 7 is a schematic diagram of a working principle of an actuator when the linear motion platform works in an embodiment.

In the figures, 1, first fixed support; 2, second fixed support; 3, metal matrix; 4, first piezoelectric assembly 5, second piezoelectric assembly; 6, driving nut; 7, rolling bearing; 8, connecting plate; 9, guide bar; 10, linear bearing; 11, objective table; 12, guiding assembly; 13, front beam; 14, rear beam; 15, first fixed bolt; 16, second fixed bolt; 17, first connecting part; 18, threaded part; 19, second connecting part; 20, first blind threaded hole; 21, second blind threaded hole; 22, piezoelectric unit; 23, first dual-partition piezoelectric ceramic plate; 24, second dual-partition piezoelectric ceramic plate; 25, third dual-partition piezoelectric ceramic plate; 26, fourth dual-partition piezoelectric ceramic plate; and 27, electrode plate.

### DETAILED DESCRIPTION

The disclosure may be implemented in many different forms and should not be construed as limited to the embodiments set forth herein. Rather, these embodiments are provided so that this disclosure will be thorough and complete, and will fully convey the concept of the disclosure to those skilled in the art. In the accompanying drawings, components are amplified for clarity.

It should be understood that although terms first, second, third and the like can be used herein to describe the components, assemblies and/or parts, the components, assemblies and/or parts are not limited by these terms. The terms are merely used to distinguish components, assemblies and/or parts from each other. Therefore, the first component, assembly and/or part discussed below can become the second component, assembly and/or part without departing from teaching of the disclosure.

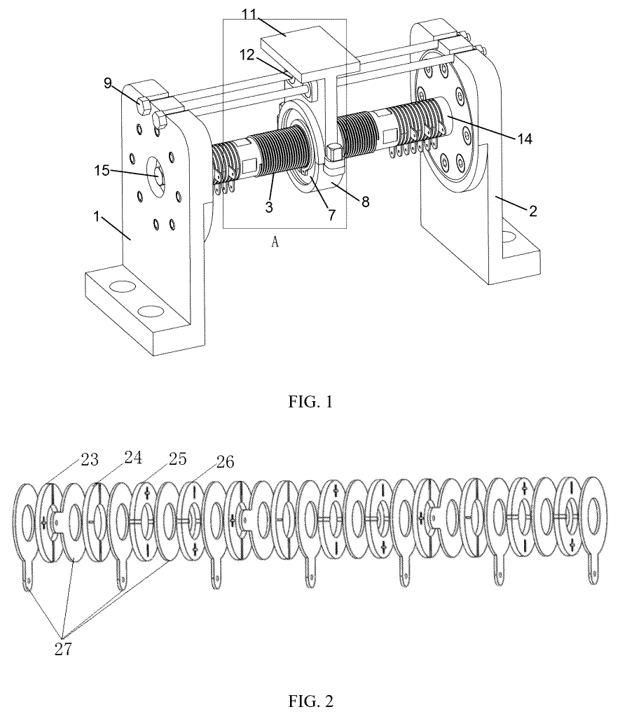

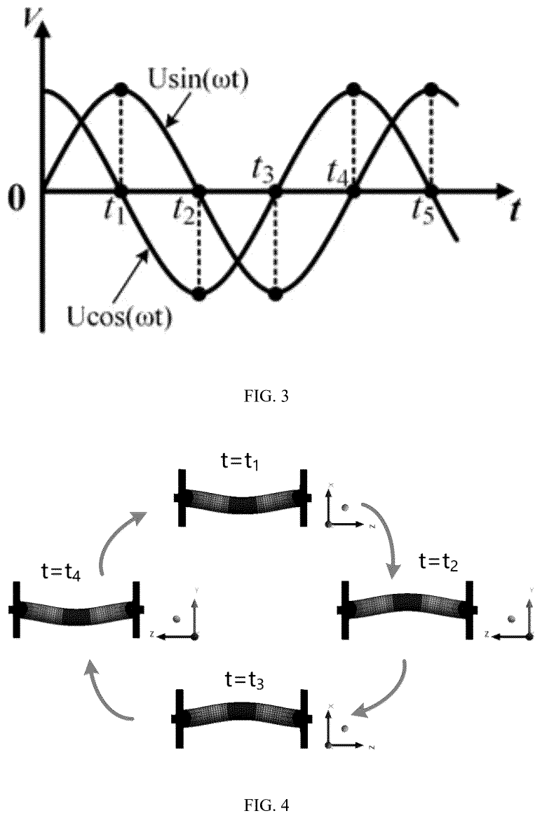

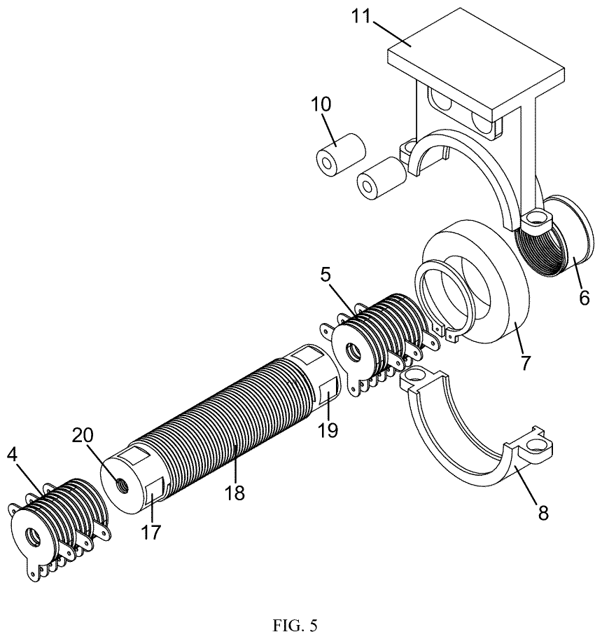

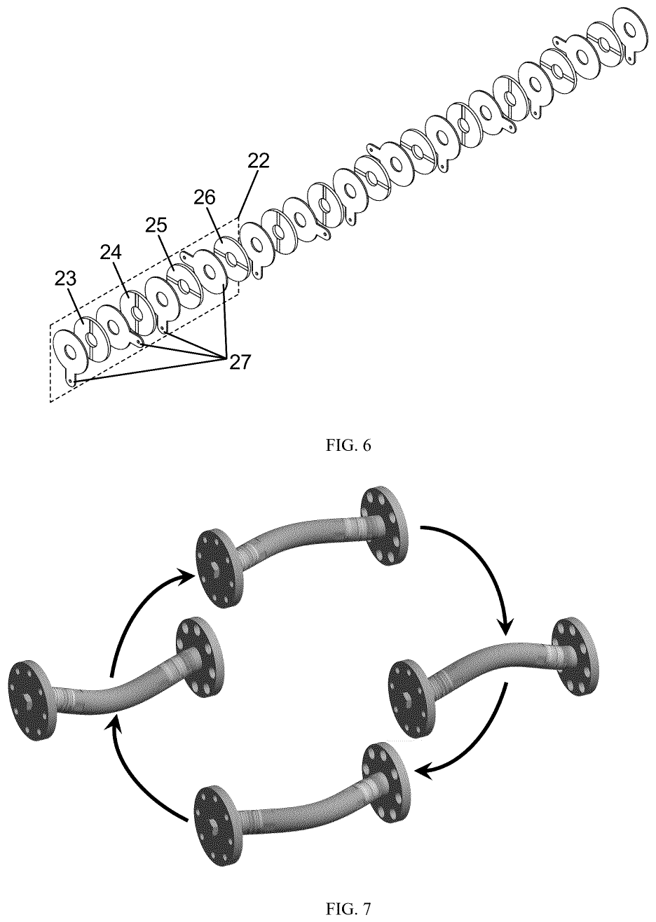

As shown in FIG. 1, this embodiment discloses a linear motion platform driven by an external thread piezoelectric actuator. FIG. 5 is an enlarged view of the partial structure at position A in FIG. 1. The linear motion platform includes an actuator, a first fixed support 1, a second fixed support 2, a rolling bearing 7, a connecting plate 8, an objective table 11, and M guide assemblies, where M is a natural number greater than or equal to 1;
the actuator includes a metal matrix 3, a driving nut 6, a first piezoelectric assembly 4, a second piezoelectric assembly 5, a front beam, a rear beam, and first and second fixed bolts;
the metal matrix 3 is cylindrical, with an external thread being arranged in the middle of an outer wall thereof, so that the outer wall includes a first connecting part, a threaded part, and a second connecting part connected in sequence, and the first connecting part and the second connecting part are symmetrical about the threaded part; a first blind threaded hole and a second blind threaded hole matching with the first fixed bolt and the second fixed bolt are formed in both ends of the metal matrix 3, respectively;
the driving nut 6 sleeves the metal matrix 3 and is in threaded connection to the metal matrix 3.
the first piezoelectric assembly 4 and the second piezoelectric assembly 5 are the same in unit structure and each include M piezoelectric units 22 laminated in sequence, where M is a natural number greater than or equal to 1;
the piezoelectric unit includes first to fourth dual-partition piezoelectric ceramic plates laminated in sequence, and an electrode plate 27 is arranged between every two adjacent piezoelectric ceramic plates;
the first to fourth dual-partition piezoelectric ceramic plates are the same in structure, all being in a shape of a circular ring, outer diameters thereof are the same as an outer diameter of a cross section of the first connecting part, and the two partitions both are polarized in a thickness direction and directions of polarization are opposite;
As shown in FIG. 2, FIG. 6 is a schematic three-dimensional view of the structure in FIG. 2, polarization boundaries of the first dual-partition piezoelectric ceramic plate 23 and the second dual-partition piezoelectric ceramic plate 24 of the linear motion platform are coplanar and the directions of polarization on the same side are opposite, polarization boundaries of the third dual-partition piezoelectric ceramic plate 25 and the fourth dual-partition piezoelectric ceramic plate 26 are coplanar and the directions of polarization on the same side are opposite, and the polarization boundaries of the second dual-partition piezoelectric ceramic plate 24 and third dual-partition piezoelectric ceramic plate 25 are perpendicular to each other;
the front beam and the rear beam are the same in structure, both being cylinders with a same cross section as that of the first connecting part, and are each provided with a through hole along an axis;
the first fixed bolt passes through the front beam and the first piezoelectric assembly 4 in sequence and is then in threaded connection to the first blind threaded hole to clamp the first piezoelectric assembly 4 between the front beam and the metal matrix 3; the second fixed bolt passes through the rear beam and the second piezoelectric assembly 5 in sequence and is then in threaded connection to the second blind threaded hole to clamp the second piezoelectric assembly 5 between the rear beam and the metal matrix 3; and the first piezoelectric assembly 4 and the second piezoelectric assembly 5 are symmetrical;
the ends of the front beam and the rear beam away from the metal matrix 3 are fixedly connected to the outside through the first fixed support 1 and the second fixed support 2, respectively;
the guide assembly includes a linear bearing 10 and a guide bar 9, wherein the linear bearing 10 sleeves outside the guide bar 9, matches with the guide bar 9, and is slidable freely relative to the guide bar 9;
the connecting plate 8 is provided with a first mounting hole for mounting the rolling bearing 7 and M second mounting holes in one-to-one correspondence to the guide assemblies;
an outer ring of the rolling bearing 7 is fixedly connected to the connecting plate 8 at the first mounting hole thereof, and an inner ring is coaxially fixedly connected to the driving nut 6;
the linear bearings 10 of the M guide assemblies are fixed in the second mounting holes corresponding thereto one by one, both ends of the guide bars 9 of the M guide assemblies are fixedly connected to the first fixed support 1 and the second fixed support 2, respectively, and the guide bars 9 of the M guide assemblies both are parallel to the metal matrix 3; and
the connecting plate 8 is fixedly connected to the objective table 11.

In this embodiment, the driving nut 6 may be in interference fit with the inner ring of the rolling bearing 7 when the driving nut is coaxially and fixedly connected to the inner ring of the rolling bearing. Moreover, a snap ring is arranged between the driving nut 6 and the inner ring of the rolling bearing 7. In the embodiment, the rolling bearing 7 is preferably the ceramic bearing.

In this embodiment, the first connecting part and the second connecting part each are circumferentially and uniformly provided with a plurality of milling planes to facilitate assembly. To facilitate assembly, the first fixed support 1 and the second fixed support 2 may also be dismantled into two parts: a disc part and a fixed part. The disc part is coaxially and fixedly connected to the actuator, and the fixed part is fixedly connected to a bottom plate, and moreover, the disc part and the fixed part are fixedly connected through a bolt. In a specific operation, the disc part of the first fixed support 1 may be integrally formed with the front beam and the disc part of the second fixed support 2 maybe integrally formed with the rear beam. Besides, to facilitate assembly, the connecting plate 8 may also be dismantled into two parts at the first mounting hole thereof.

This embodiment further discloses a working method of the linear motion platform driven by an external thread piezoelectric actuator, including the following steps:
1) if it is needed to drive the objective table 11 to move forward:
grounding the metal matrix 3, applying a first signal to the first and second piezoelectric ceramic plates 4, 5 of each piezoelectric unit in the first and second piezoelectric assemblies 4, 5, and applying a second signal to the third and fourth piezoelectric ceramic plates of each piezoelectric unit in the first and second piezoelectric assemblies, where the first and second signals are sinusoidal voltage signals with a phase difference of π/2, as shown in FIG. 3, so that particles on the thread of the metal matrix 3 vibrate at a high frequency, and with a small amplitude, FIG. 4 is a simulated schematic diagram (t1-t2 are time sequences) and FIG. 7 is a schematic diagram of the principle, to enable the driving nut 6 to rotate through a rubbing action; the connecting plate 8 driven by the driving unit 6 moves forward to drive the objective table 11 to move forward; and
2) if it is needed to drive the objective table 11 to move reversely, just adjusting the phase difference between the first and second signals as −π/2.

Those skilled in the art can understand that, all terms (including technical and scientific terms) used herein have the same meaning as commonly understood by those of ordinary skill in the art to which the disclosure belongs, unless otherwise defined. It should be further understood that those terms defined in a general dictionary should be understood as having meanings consistent with the meanings in the context in the prior art. Unless otherwise defined herein, those terms will not be explained by idealized or too formal implications.

There are many specific implementations of the disclosure, and the above is only a preferred implementation of the disclosure. It should be noted that, for those of ordinary skill in the art, without deviating from the principle of the disclosure, several improvements can be made, and the improvements shall also be regarded as the protection scope of the disclosure.

1. A linear motion platform driven by an external thread piezoelectric actuator, wherein the linear motion platform comprises an actuator, a first fixed support (1), a second fixed support (2), a rolling bearing (7), a connecting plate (8), an objective table (11), and M guide assemblies (12), wherein M is a natural number greater than or equal to 1;
the actuator comprises a metal matrix (3), a driving nut (6), a first piezoelectric assembly (4), a second piezoelectric assembly (5), a front beam (13), a rear beam (14), a first fixed bolt (15) and a second fixed bolt (16);
the metal matrix (3) is cylindrical, with an external thread being arranged in the middle of an outer wall thereof, so that the outer wall comprises a first connecting part (17), a threaded part (18), and a second connecting part (19) connected in sequence, and the first connecting part (17) and the second connecting part (19) are symmetrical about the threaded part; a first blind threaded hole (20) and a second blind threaded hole (21) matching with the first fixed bolt (15) and the second fixed bolt (16) are formed in both ends of the metal matrix (3), respectively;
the driving nut (6) sleeves the metal matrix (3) and is in threaded connection to the metal matrix (3);
the first piezoelectric assembly (4) and the second piezoelectric assembly (5) are the same in unit structure and each comprise M piezoelectric units (22) laminated in sequence, wherein M is a natural number greater than or equal to 1;
the piezoelectric unit (22) comprises a first dual-partition piezoelectric ceramic plate (23), a second dual-partition piezoelectric ceramic plate (24), a third dual-partition piezoelectric ceramic plate (25) and a fourth dual-partition piezoelectric ceramic plate (26) laminated in sequence, and an electrode plate (27) is arranged between every two adjacent piezoelectric ceramic plates;
the first dual-partition piezoelectric ceramic plate, the second dual-partition piezoelectric ceramic plate, the third dual-partition piezoelectric ceramic plate and to the fourth dual-partition piezoelectric ceramic plate are the same in structure, all being in a shape of a circular ring, outer diameters thereof are the same as an outer diameter of a cross section of the first connecting part, and the two partitions both are polarized in a thickness direction and directions of polarization are opposite;
polarization boundaries of the first dual-partition piezoelectric ceramic plate and the second dual-partition piezoelectric ceramic plate are coplanar and the directions of polarization on the same side are opposite, polarization boundaries of the third dual-partition piezoelectric ceramic plate and the fourth dual-partition piezoelectric ceramic plate are coplanar and the directions of polarization on the same side are opposite, and the polarization boundaries of the second dual-partition piezoelectric ceramic plate and third dual-partition piezoelectric ceramic plate are perpendicular to each other;
the front beam (13) and the rear beam (14) are the same in structure, both being cylinders with a same cross section as that of the first connecting part, and are each provided with a through hole along an axis;
the first fixed bolt (15) passes through the front beam (13) and the first piezoelectric assembly (4) in sequence and is then in threaded connection to the first blind threaded hole (20) to clamp the first piezoelectric assembly (4) between the front beam (13) and the metal matrix (3); the second fixed bolt (16) passes through the rear beam and the second piezoelectric assembly (5) in sequence and is then in threaded connection to the second blind threaded hole (21) to clamp the second piezoelectric assembly (5) between the rear beam (14) and the metal matrix (3); and the first piezoelectric assembly (4) and the second piezoelectric assembly (5) are symmetrical;
the ends of the front beam (13) and the rear beam (14) away from the metal matrix (3) are fixedly connected to the outside through the first fixed support (1) and the second fixed support (2), respectively;
the guide assembly (12) comprises a linear bearing (10) and a guide bar (9), wherein the linear bearing (10) sleeves outside the guide bar (9), matches with the guide bar (9), and is slidable freely relative to the guide bar (9);
the connecting plate (8) is provided with a first mounting hole for mounting the rolling bearing (7) and M second mounting holes in one-to-one correspondence to the guide assemblies (12);
an outer ring of the rolling bearing (7) is fixedly connected to the connecting plate (8) at the first mounting hole thereof, and an inner ring is coaxially fixedly connected to the driving nut (6);
the linear bearings (10) of the M guide assemblies (12) are fixed in the second mounting holes corresponding thereto one by one, both ends of the guide bars (9) of the M guide assemblies are fixedly connected to the first fixed support (1) and the second fixed support (2), respectively, and the guide bars (9) of the M guide assemblies both are parallel to the metal matrix (3); and
the connecting plate (8) is fixedly connected to the objective table (11).

2. The linear motion platform driven by an external thread piezoelectric actuator according to claim 1, wherein the driving nut (6) is in interference fit with the inner ring of the rolling bearing (7), and a snap ring is arranged between the driving nut (6) and the inner ring of the rolling bearing (7).

3. The linear motion platform driven by an external thread piezoelectric actuator according to claim 1, wherein the rolling bearing (7) is a ceramic bearing.

4. The linear motion platform driven by an external thread piezoelectric actuator according to claim 1, wherein the first connecting part (17) and the second connecting part (19) each are circumferentially and uniformly provided with a plurality of milling planes.

5. A working method of the linear motion platform driven by an external thread piezoelectric actuator according to claim 1, comprising the following steps:
if it is needed to drive the objective table to move forward:
grounding the metal matrix, applying a first signal to the first and second piezoelectric ceramic plates of each piezoelectric unit in the first and second piezoelectric assemblies, and applying a second signal to the third and fourth piezoelectric ceramic plates of each piezoelectric unit in the first and second piezoelectric assemblies, wherein the first and second signals are sinusoidal voltage signals with a phase difference of π/2, so that particles on the thread of the metal matrix vibrate at a high frequency and with a small amplitude to enable the driving nut to rotate through a rubbing action; the connecting plate driven by the driving unit moves forward to drive the objective table to move forward; and
if it is needed to drive the objective table to move reversely, just adjusting the phase difference between the first and second signals as −π/2.
